(19) United States
(12) Patent Application Publication
(10) Pub. No.: US 2026/0130266 A1
(43) Pub. Date: May 7, 2026

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Hsin-Yu CHEN, Taipei City (TW); Yu-Hsiang HU, Hsinchu City (TW); Chien-Sheng CHEN, Hsinchu City (TW); Chien-Hsun LEE, Hsin-chu County (TW); Kathy Wei YAN, Hsinchu (TW)

(73) Assignee: Taiwan Semiconductor Manufacturing Company, Ltd., Hsinchu (TW)

(21) Appl. No.: 18/939,720

(22) Filed: Nov. 7, 2024

(51) Int. Cl. H01L 23/31; H01L 21/56; H01L 21/683; H01L 23/00; H01L 23/16; H01L 23/498; H01L 25/16

(52) U.S. Cl. CPC H10W 74/10; H10P 72/7402; H10W 74/014; H10W 74/016; H10W 90/00; H10W 72/0198; H10W 72/29; H10W 72/334; H10W 74/15; H10W 76/40; H10W 90/401; H10W 90/724; H10W 90/734

(57) ABSTRACT

A package structure is provided. The package structure includes a device die bonded to a package substrate via a plurality of connectors. The package structure includes a dummy die bonded to the package substrate via a plurality of dummy connectors and disposed adjacent to the device die. The dummy die includes a base portion, an upper portion bonded to the base portion, and an edge molding material formed over the base portion and surrounding the upper portion. The package structure also includes a package molding material over the package substrate and around the dummy die and the device die. The Young's modulus of the edge molding material is less than the Young's modulus of the package molding material.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Although existing methods of fabricating semiconductor structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 illustrates a schematic view of the first package component in accordance with some embodiments.

FIGS. 2A through 2E illustrates cross-sectional views of intermediate steps during a process for fabricating a dummy die in accordance with some embodiments.

FIG. 3A through 3L illustrates cross-sectional views of intermediate steps during a process for fabricating the package structure along the line A-A shown in FIG. 1 in accordance with some embodiments.

FIG. 4 illustrates an enlarged view of the region C shown in FIG. 3L in accordance with some embodiments.

FIG. 5 illustrates an enlarged view of the region B shown in FIG. 1 in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and methods for fabricating the same are provided. The package structure includes a dummy die disposed adjacent to the device die, and the dummy die includes an edge molding material on edges of the dummy die. The dummy die is disposed at a corner of the package molding material. The Young's modulus of the edge molding material is less than the Young's modulus of the package molding material around the dummy die and the device die. As a result, the edge molding material of the dummy die can mitigate the coefficient of thermal expansion (CTE) mismatch between the dummy die and the package molding material, and therefore the corner stress of the package structure can be reduced. In this way, cracks or other defects can be minimized for the package structure.

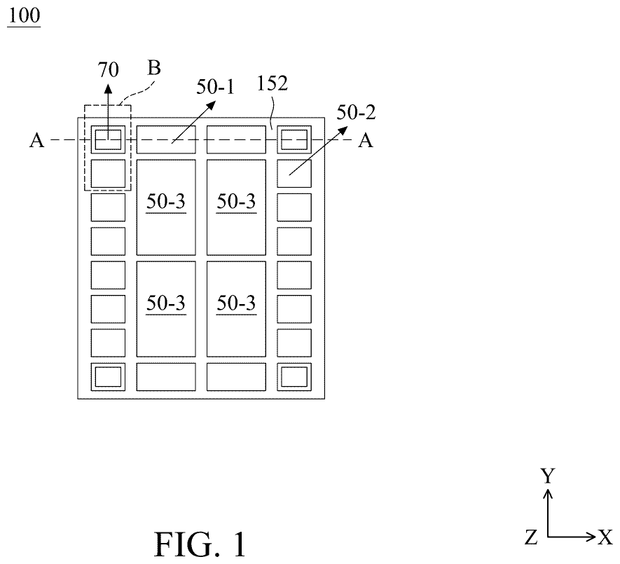

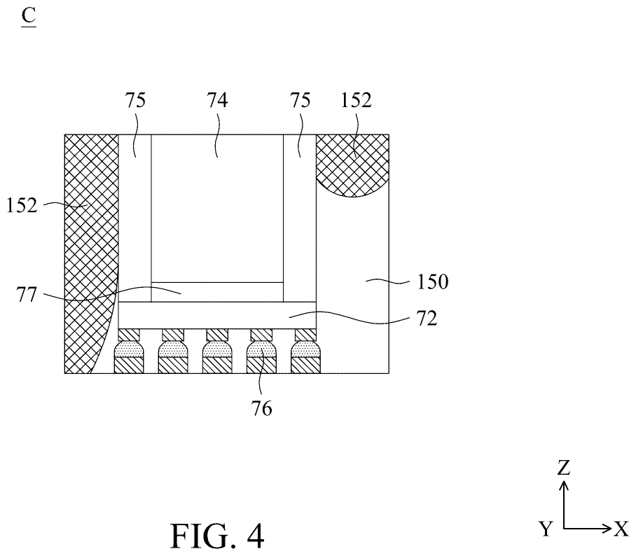

FIG. 1 illustrates a schematic view of a first package component 100 in accordance with some embodiments. As shown in FIG. 1 the first package component 100 includes a plurality of dummy dies 70 and a plurality of device dies 50-1, 50-2, and 50-3 that are encapsulated by the package molding material 152. In some embodiments, the dummy dies 70 are located at corners of the first package component 100 (that is, the corners of the package molding material 152), and the device dies 50-1, 50-2, and 50-3 are disposed between two of the dummy dies 70. In some embodiments, the device dies 50-1 are located on upper and lower sides of the first package component 100, the device dies 50-2 are located on left and right sides of the first package component 100, and the device dies 50-3 are located at the center of the first package component 100. For example, the device dies 50-1 may be input/output (I/O) dies, the device dies 50-2 may be memory dies (such as (HBM) dies), and the device dies 50-3 may be system-on-chip (SoC) dies or system-on-integrated-circuit (SoIC) dies. However, the present disclosure is not limited thereto. In some embodiments, the dummy dies 70 each include an edge molding material 75 on edges of the dummy dies 70. The Young's modulus of the edge molding material 75 is less than the Young's modulus of the package molding material 152 around the dummy dies 70 and the device dies 0-1, 50-2, and 50-3. The formation of the first package component 100 will be further discussed below in accompany with FIGS. 4A through 4L.

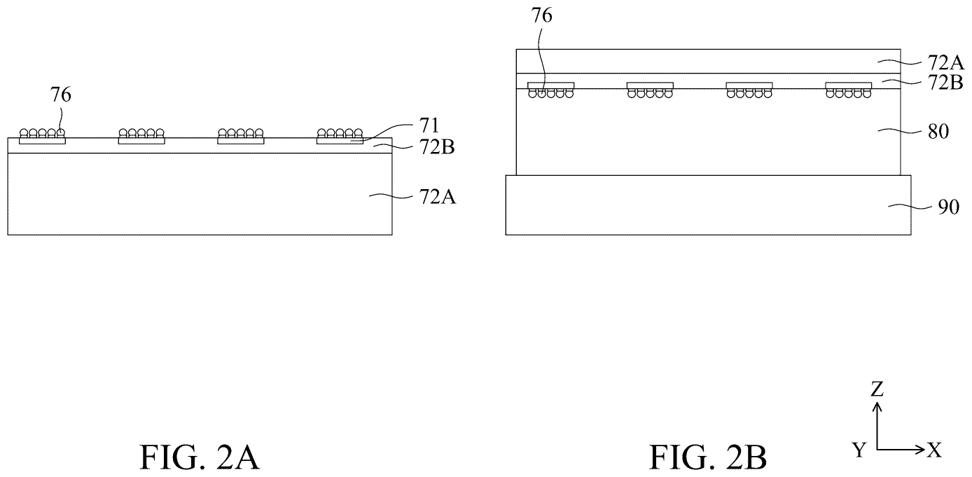

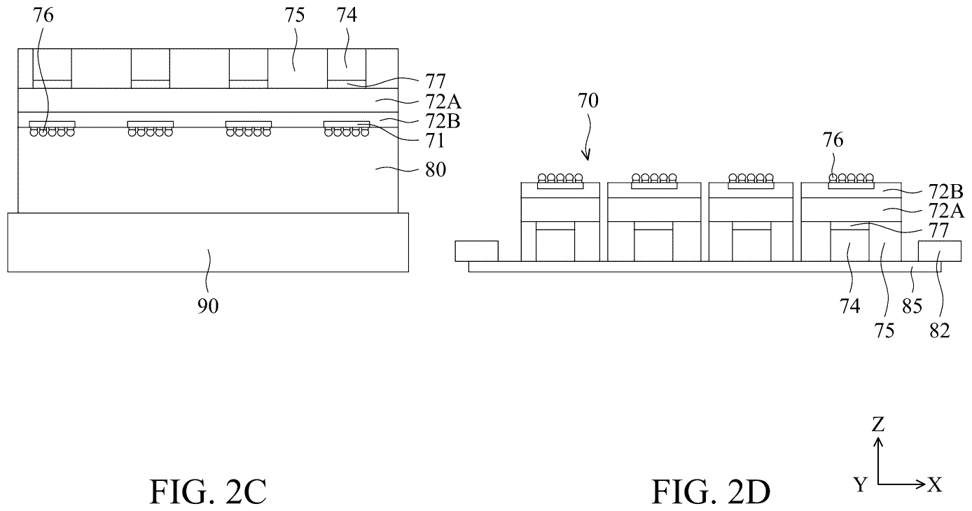

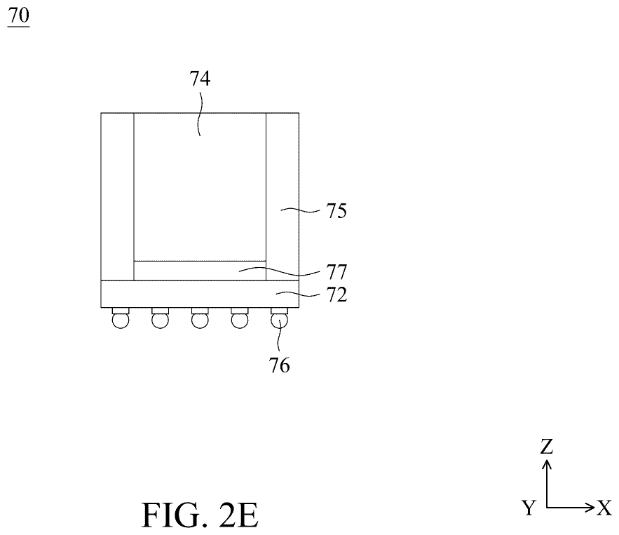

FIGS. 2A through 2E illustrates cross-sectional views of intermediate steps during a process for fabricating a dummy die 70 in accordance with some embodiments. As shown in FIG. 2A, a dielectric layer 72B is formed on a base 72A and a plurality of pads 71 are embedded in the dielectric layer 72B. For example, the base 72A includes a semiconductor material, such as silicon, germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the dielectric layer 72B includes a dielectric material, such as Phospho-Silicate Glass (PSG), Boro-Silicate Glass (BSG), Boron-Doped Phospho-Silicate Glass (BPSG), undoped Silicate Glass (USG), or the like.

In addition, a plurality of connectors 76 are disposed over the dielectric layer 72B and connected to the pads 71. The connectors 76 and the pads 71 are provided for the connection of the dummy die 70 that is subsequently formed. Since the connectors 76 and the pads 71 would not be electrically connected to the active devices (such as the device dies 50-1, 50-2, 50-3, etc.), the connectors 76 may also be referred to as the dummy connectors 76, and the pads 71 may also be referred to as the dummy pads 71 in the following paragraphs.

Then, as shown in FIG. 2B, an attach film 80 is provided over the dummy connectors 76 so as to bond the dielectric layer 72B to a carrier 90. In some embodiments, the carrier 90 may be a glass carrier substrate, a ceramic carrier substrate, or the like. In some embodiments, the attach film 80 is formed of a polymer-based material, which may be removed along with the carrier 90 from the overlying structures that will be formed in subsequent steps. In some embodiments, the attach film 80 is an epoxy-based thermal-release material, which loses its adhesive property when heated, such as a light-to-heat-conversion (LTHC) release coating. In other embodiments, the attach film 80 may be an ultra-violet (UV) glue, which loses its adhesive property when exposed to UV lights. In some embodiments, the attach film 80 may be dispensed as a liquid and cured, may be a laminate film laminated onto the carrier 90, or may be the like. In some embodiments, after the dummy connectors 76 on the dielectric layer 72B is bonded to the carrier 90, the base 72A is thinned down so as to provide space for the edge molding material 75 that is subsequently formed.

Next, as shown in FIG. 2C, a plurality of upper portions 74 are bonded to the bonding to the base 72A via a bonding film 77. In some embodiments, the upper portions 74 include a semiconductor material, such as silicon, germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the material of the base 72A is the same as that of the upper portions 74. However, the present disclosure is not limited thereto. In some embodiments, the bonding film 77 may include an adhesive material or be a dielectric film, which includes Si, SiON, SiO₂, etc. In addition, an edge molding material 75 is formed over the base 72A and around the upper portions 74. In some embodiments, the edge molding material 75 is formed over the top surfaces of the upper portions 74, and then a planarization process is performed to the edge molding material 75 so as to expose the top surfaces of the upper portions 74.

It should be noted that the Young's modulus of the edge molding material 75 is less than the Young's modulus of the package molding material 152. Accordingly, the edge molding material 75 can mitigate the coefficient of thermal expansion (CTE) mismatch between the dummy die 70 and the package molding material 152, and therefore the corner stress of the first package component 100 can be reduced. In some embodiments, the glass transition temperature (Tg) of the edge molding material 75 is less than that of the package molding material 152 (for example, shown in FIG. 1).

Then, as shown in FIG. 2D, the attach film 80 and the carrier 90 are removed from the dummy connectors 76. After the attach film 80 and the carrier 90 are removed, the overall structure is flipped and placed on a tape 85, which may be supported by the frame 82. In some embodiments, a singulation process is performed along scribe lines (not individually shown) between the adjacent upper portions 74 to form a plurality of dummy dies 70. In some embodiments, the width of the edge molding material 75 around the upper portion 74 of the dummy die 70 is constant. In some embodiments, the width of the edge molding material 75 on one side of the dummy die 70 is ranged from about 1 nm to about 3000 nm. However, the present disclosure is not limited thereto.

As shown in FIG. 2E, the singulated dummy dies 70 are picked from the tape 85. It should be noted that for the sake of brevity, the base 72A and the dielectric layer 72B are collectively referred to as a base portion 72 of the dummy die 70. In some embodiments, the depth of the base portion 72 is ranged from about 100 μm to about 300 μmin the horizontal direction (such as the Z direction). Accordingly, the base portion 72 may have sufficient structural strength to support the upper portion 74 and the edge molding material 75, and may provide space for arranging sufficient edge molding material 75 to reduce the edge stress of the package structure. In some embodiments, the depth of the upper portion 74 is greater than the depth of the base portion 72 in the horizontal direction (such as the Z direction).

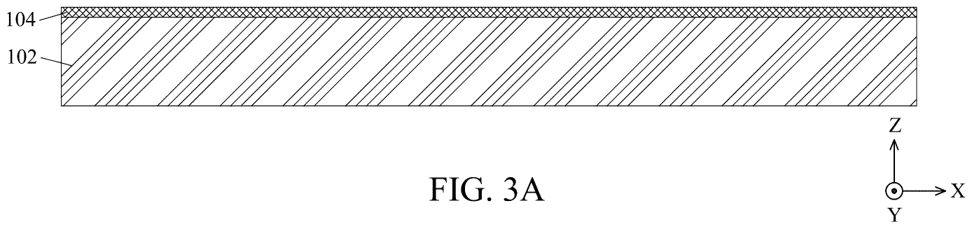

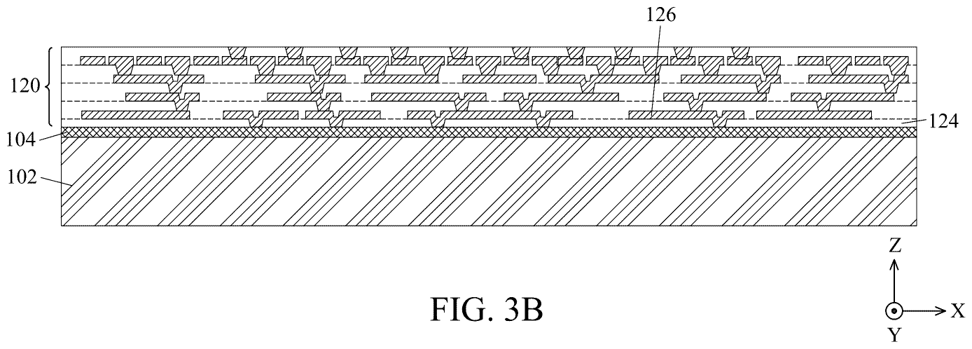

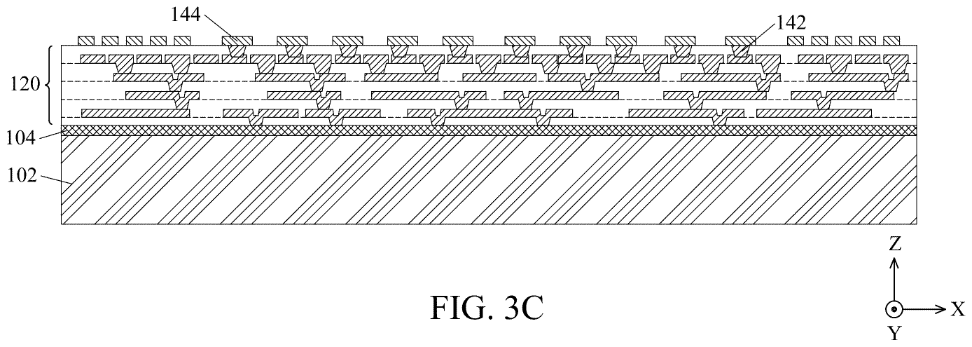

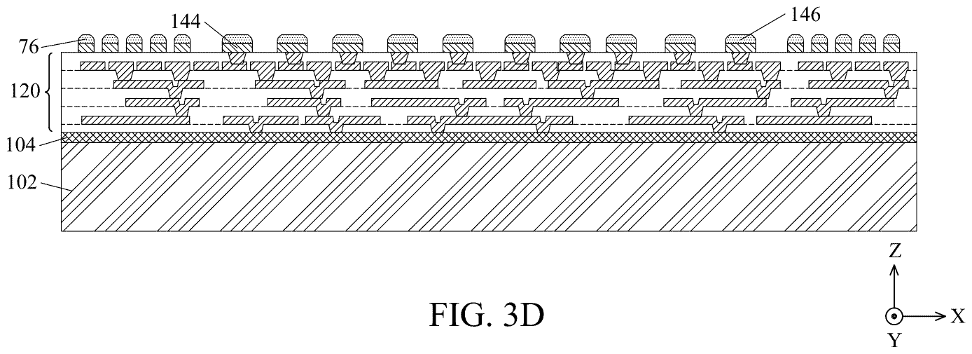

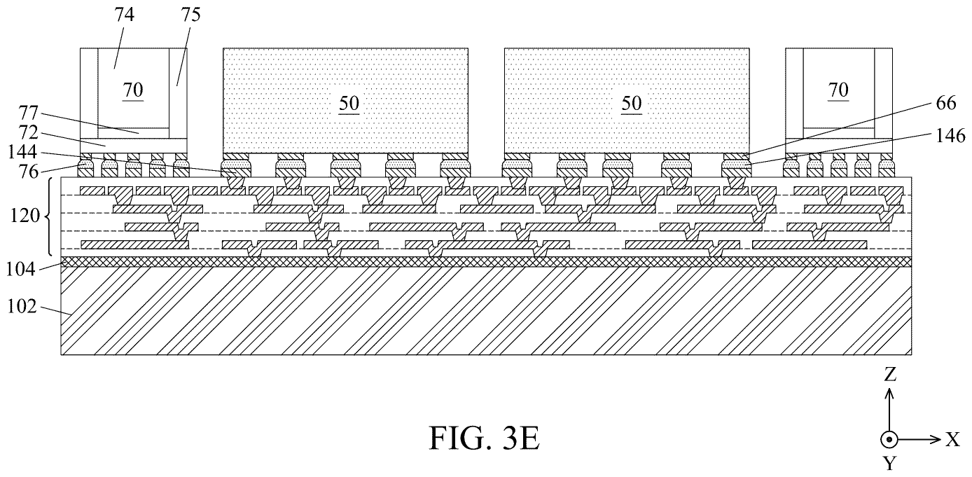

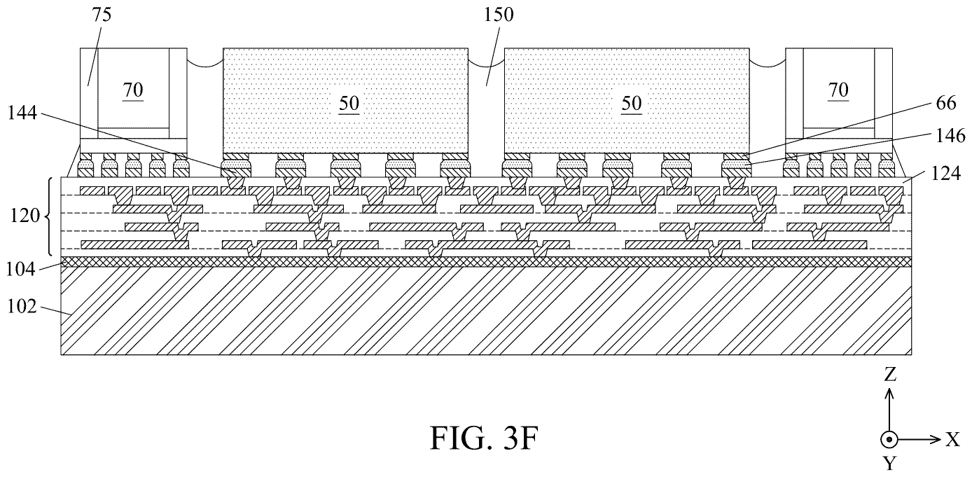

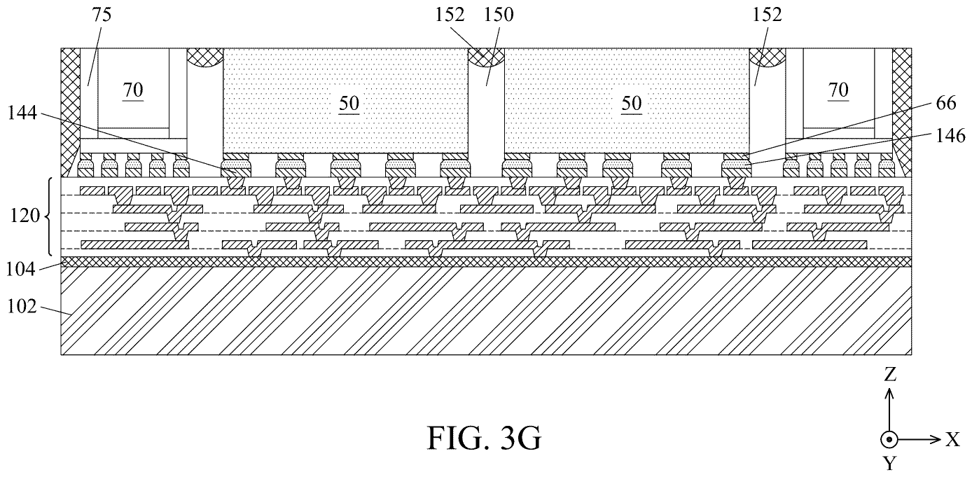

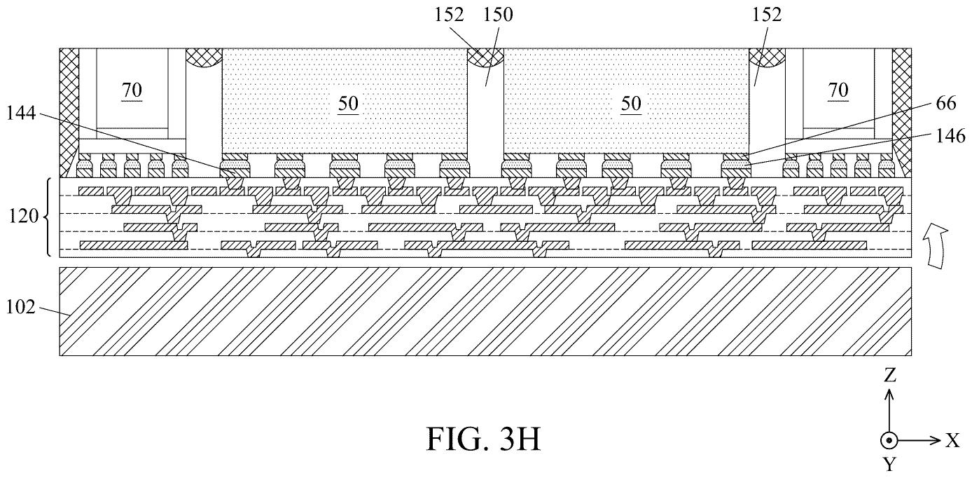

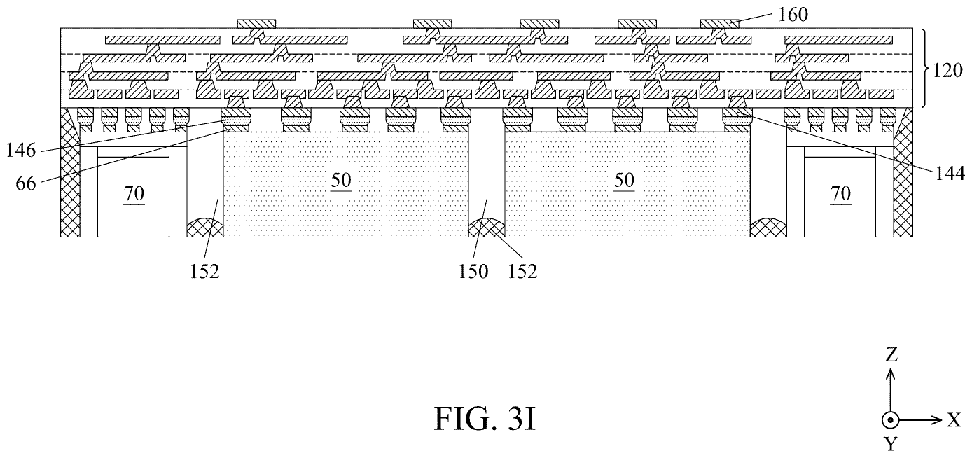

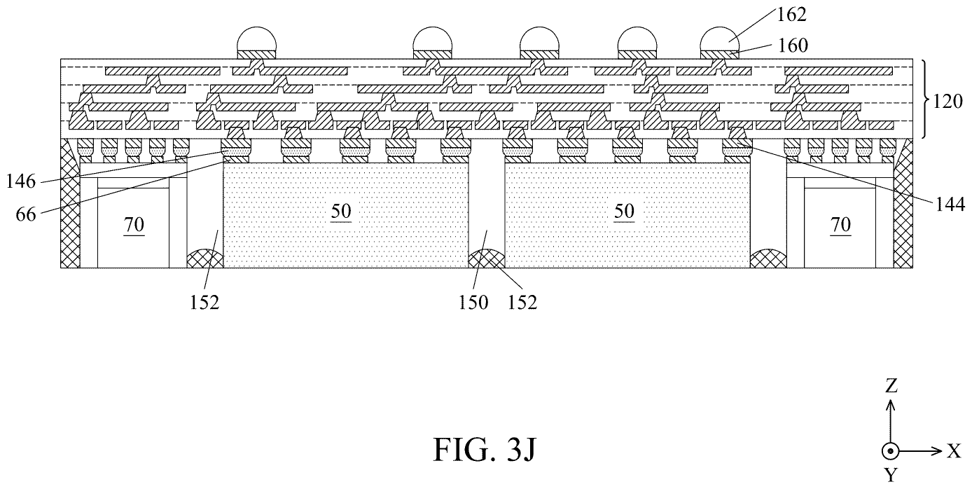

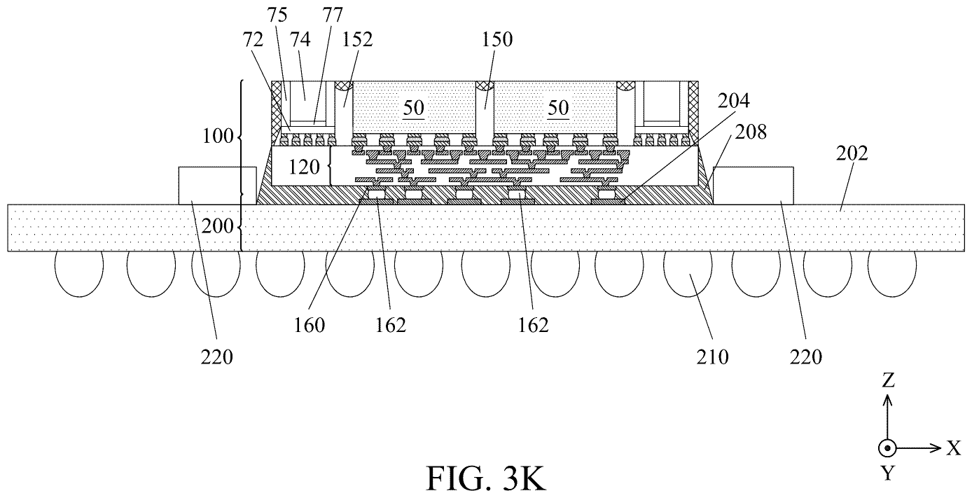

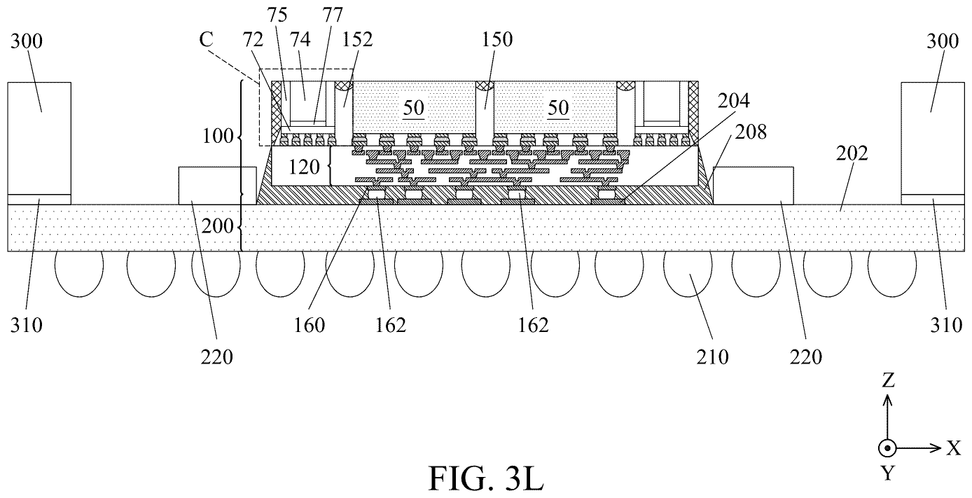

FIGS. 3A through 3L illustrate cross-sectional views of intermediate steps during a process for forming a package structure 10, in accordance with some embodiments. In some embodiments, multiple device dies 50 are packaged to form an integrated circuit package. In some embodiments, the integrated circuit packages may also be referred to as integrated fan-out (InFO) packages. However, the present disclosure is not limited thereto. It should be noted that a plurality of first package components 100 may be formed in a wafer and singulated in the processes. For the sake of clarity and simplicity, one first package component 100 is shown in the present disclosure.

As shown in FIG. 3A, a carrier substrate 102 is provided, and a release layer 104 is formed on the carrier substrate 102. The carrier substrate 102 may be a glass carrier substrate, a ceramic carrier substrate, or the like. In some embodiments, the carrier substrate 102 includes a wafer, such that multiple packages can be formed on the carrier substrate 102 simultaneously.

In some embodiments, the release layer 104 is formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. In some embodiments, the release layer 104 may be dispensed as a liquid and cured, may be a laminate film laminated onto the carrier substrate 102, or may be the like. In some embodiments, the top surface of the release layer 104 is leveled and has a high degree of planarity.

As shown in FIG. 3B, a redistribution structure 120 is formed over the release layer 104. In some embodiments, the metallization patterns may also be referred to as redistribution layers or redistribution lines. The redistribution structure 120 is shown as an example having multiple layers of metallization patterns 126 and dielectric layers 124 that are alternatively stacked. In some embodiments, the dielectric layer 124 is formed of a photo-sensitive material such as PBO, polyimide, BCB, or the like, which may be patterned using a lithography mask. In some embodiments, the dielectric layers 124 are formed by spin coating, lamination, CVD, the like, or a combination thereof. In some embodiments, the dielectric layer 124 may be patterned by an acceptable process, such as by exposing and developing the dielectric layers 124 to light when the dielectric layers 124 are a photo-sensitive material or by etching using, for example, an anisotropic etch.

In some embodiments, the metallization patterns 126 include conductive elements extending along the major surface of the dielectric layers 124 and extending through the dielectric layers 124. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the metallization pattern 126. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

As shown in FIG. 3C, conductive vias 142 are then formed in the redistribution structure 120. As an example to form the conductive vias 142, a seed layer is formed in the openings extending through the dielectric layer 124. In some embodiments, the seed layer is a metal layer, which is a single layer or a composite layer comprising a plurality of sub-layers formed of different materials. In some embodiments, the seed layer comprises a titanium layer and a copper layer over the titanium layer. In some embodiments, the seed layer is formed using, for example, PVD or the like. A conductive material is then formed on the seed layer in the openings. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the conductive vias 142.

In some embodiments, under-bump metallurgies (UBMs) 144 are formed for external connection to the conductive vias 142. The UBMs 144 may be referred to as pads 144. The UBMs 144 have bump portions on and extending along the major surface of the dielectric layer 124 and physically and electrically couple the conductive vias 142. In some embodiments, the UBMs 144 are formed of the same material as the conductive vias 142. In some embodiments, the UBMs 144 includes alloys such as electroless nickel, electroless palladium, immersion gold, electroless nickel, or the like.

As shown in FIG. 3D, conductive connectors 146 are formed on the UBMs 144. In some embodiments, the conductive connectors 146 includes ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 146 includes a conductive material such as solder, copper, aluminum, gold, nickel, silver, palladium, tin, the like, or a combination thereof. In some embodiments, the conductive connectors 146 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 146 comprise metal pillars (such as a copper pillar) formed by sputtering, printing, electro plating, electroless plating, CVD, or the like. In some embodiments, the metal pillars are solder free and have substantially vertical sidewalls. In some embodiments, a metal cap layer is formed on the top of the metal pillars. In some embodiments, the metal cap layer includes nickel, tin, tin-lead, gold, silver, palladium, indium, nickel-palladium-gold, nickel-gold, the like, or a combination thereof and may be formed by a plating process.

As shown in FIG. 3E, device dies 50 and dummy dies 70 are attached to the structure of FIG. 3D. A desired type and quantity of device dies 50 and dummy dies 70 are adopted. It should be noted that the device die 50 shown in FIG. 3E may be any of the device dies 50-1, 50-2, and 50-3 that are discussed above with reference to FIG. 1. In some embodiments, the device dies 50 are referred to as package modules. In the embodiment shown, multiple device dies 50 are adhered adjacent one another. For example, one of the device dies 50 may be a logic device, such as a central processing unit (CPU), a graphics processing unit (GPU), a system-on-a-chip (SoC), a microcontroller, or the like. The other device die 50 may be a memory device, such as a dynamic random access memory (DRAM) die, a static random access memory (SRAM) die, a hybrid memory cube (HMC) module, a high bandwidth memory (HBM) module, or the like. In some embodiments, the device dies 50 are the same type of dies, such as SoC dies. In some embodiments, the device dies 50 are formed in the processes of the same technology node, or they are formed in the processes of different technology nodes. For example, one of the device dies 50 may be of a more advanced process node than the other of the device dies 50. The device dies 50 may be different sizes (e.g., different heights and/or surface areas), or they may be the same size (e.g., the same height and/or surface area).

In some embodiments, the device dies 50 are attached to the conductive connectors 146. That is, the die connectors 66 of the device dies 50 are connected to the conductive connectors 146 opposite the UBMs 144. In some embodiments, the conductive connectors 146 are reflowed to attach the device dies 50 to the UBMs 144. The conductive connectors 146 electrically and/or physically couple the redistribution structure 120, including metallization patterns in the redistribution structure 120, to the device dies 50. It should be noted that although the dummy dies 70 are disposed adjacent to the device dies 50, the dummy dies 70 are electrically isolated from the device dies 50. In particular, there is no electric signal transmitted to the dummy dies 70, which are provided for mitigating the corner stress of the package structure.

In some embodiments, the conductive connectors 146 have an epoxy flux (not shown) formed thereon before they are reflowed with at least some of the epoxy portion of the epoxy flux remaining after the device dies 50 are attached to the redistribution structure 120. This remaining epoxy portion may act as an underfill to reduce stress and protect the joints resulting from reflowing the conductive connectors 146.

As shown in FIG. 3F, an underfill 150 is formed between the device dies 50, the dummy dies 70, and the dielectric layer 124, including between and around the UBMs 144, the conductive connectors 146, and the die connectors 66. In some embodiments, the underfill 150 is formed by a capillary flow process after the device dies 50 and the dummy dies 70 are attached or is formed by a suitable deposition method before the device dies 50 and the dummy dies 70 are attached. In some embodiments, the underfill 150 is also between the device dies 50 and the dummy dies 70. In some embodiments, the underfill 150 may partially fill the gap between adjacent two of the device dies 50 and the dummy dies 70. However, the present disclosure is not limited thereto.

As shown in FIG. 3G, a package molding material 152 is formed around the device dies 50 the dummy dies 70, the conductive connectors 146, and the underfill 150. After formation, the package molding material 152 encapsulates the conductive connectors 146, the device dies 50 and the dummy dies 70. In some embodiments, the package molding material 152 is a molding compound, epoxy, or the like. In some embodiments, the package molding material 152 is applied by compression molding, transfer molding, or the like. In some embodiments, the package molding material 152 is applied in liquid or semi-liquid form and then subsequently cured. In some embodiments, a planarization step may be performed to remove and planarize an upper surface of the package molding material 152. In some embodiments, surfaces of the underfill 150, the package molding material 152, the device dies 50, and the dummy dies 70 are coplanar (within process variation). In this way, the package molding material 152 may also fill the gaps between adjacent two of the device dies 50 and the dummy dies 70.

As shown in FIG. 3H, a carrier substrate de-bonding is performed to detach (or “de-bond”) the carrier substrate 102 from the redistribution structure 120, e.g., the dielectric layer 124. In accordance with some embodiments, the de-bonding includes projecting a light such as a laser light or an UV light on the release layer 104 so that the release layer 104 decomposes under the heat of the light and the carrier substrate 102 can be removed. The structure is then flipped over and placed on a tape (not shown).

As shown in FIG. 3I, UBMs 160 are formed for external connection to the redistribution structure 120, e.g., the metallization pattern 126. The UBMs 160 have bump portions on and extending along the major surface of the dielectric layer 124. In some embodiments, the UBMs 160 are formed of the same material as the metallization pattern 126.

As shown in FIG. 3J, conductive connectors 162 are formed on the UBMs 160. The conductive connectors 162 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 162 include a conductive material such as solder, copper, aluminum, gold, nickel, silver, palladium, tin, the like, or a combination thereof. In some embodiments, the conductive connectors 162 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 162 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. Accordingly, the first package component 100 is formed.

As shown in FIG. 3K, the first package component 100 may be mounted on the second package component 200 using the conductive connectors 162. The second package component 200 includes a package substrate 202 and bond pads 204 over the package substrate 202. In some embodiments, the package substrate 202 is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, in some embodiments, the package substrate 202 is a semiconductor-on-insulator (SOI) substrate. Generally, an SOI substrate includes a layer of a semiconductor material such as epitaxial silicon, germanium, silicon germanium, SOI, SGOI, or combinations thereof. The package substrate 202 is, in one alternative embodiment, based on an insulating core such as a fiberglass reinforced resin core. One example core material is fiberglass resin. Alternatives for the core material include bismaleimide-triazine (BT) resin, or alternatively, other PCB materials or films. Build up films or other laminates may be used for package substrate 202.

In some embodiments, the second package component 200 includes bump structures 210. In some embodiments, the bump structures 210 may be conductive ball structures (such as ball grid array (BGA)), conductive pillar structures, or conductive paste structures that are mounted on and electrically coupled to the package substrate 202 in the bonding process.

In some embodiments, one or more electronic component 220 is formed on the second package component 200. The electronic component 220 is bonded to and exposed from the package substrate 202. In some embodiments, the electronic component 220 is embedded in the package substrate 202. In some embodiments, the electronic component 220 may be active and/or passive devices. In some embodiments, the electronic component 220 is in contact with the underfill 208. However, the present disclosure is not limited thereto. For example, the electronic component 220 may be a wide variety of devices such as transistors, capacitors, resistors, combinations of these, and the like may be used to generate the structural and functional requirements of the design for the device stack. In some embodiments, the electronic components are formed using any suitable methods.

The package substrate 202 may also include metallization layers and vias (not shown), with the bond pads 204 being physically and/or electrically coupled to the metallization layers and vias. In some embodiments, the metallization layers are formed over the active and passive devices and are designed to connect the various devices to form functional circuitry. In some embodiments, the metallization layers are formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the package substrate 202 is substantially free of active and passive devices.

In some embodiments, the conductive connectors 162 are reflowed to attach the first package component 100 to the bond pads 204. The conductive connectors 162 electrically and/or physically couple the second package component 200, including metallization layers in the package substrate 202, to the first package component 100. In some embodiments, the conductive connectors 162 have an epoxy flux (not shown) formed thereon before they are reflowed with at least some of the epoxy portion of the epoxy flux remaining after the first package component 100 is attached to the second package component 200. This remaining epoxy portion may act as an underfill to reduce stress and protect the joints resulting from reflowing the conductive connectors 162. In some embodiments, an underfill 208 is formed between the first package component 100 and the second package component 200 and surrounding the conductive connectors 162. In some embodiments, the underfill 208 is formed by a capillary flow process after the second package component 200 is attached or may be formed by a suitable deposition method before the second package component 200 is attached.

As shown in FIG. 3L, a ring structure 300 is bonded to the second package component 200 (in particular, the package substrate 202) via an adhesive film 310. As a result, the package structure 10 is formed. In some embodiments, the ring structure 300 is configured to reduce the warpage of the package structure 10 and protect the electronic component 220. Optionally, a thermal interface material and a heat spreader may be disposed over the first package component 100 so as to facilitate the thermal dissipation of the package structure 10. It should be noted that the package structure 10 may also include other components to achieve desired functions, and these configurations are also contemplated within the scope of the present disclosure.

FIG. 4 illustrates an enlarged view of the region C shown in FIG. 3L in accordance with some embodiments. As shown in FIG. 4, the underfill 150 is sandwiched between the edge molding material 75 and the package molding material 152. In particular, the underfill 150 extends into a gap between the edge molding material 75 and the package molding material 152, and covers a portion of a sidewall of the edge molding material 75. In some embodiments, the package molding material 152 is in contact with the edge molding material 75. That is, an interface may be formed between the edge molding material 75 and the package molding material 152. In some embodiments, the edge molding material 75 covers the upper surface of the base portion 72, the sidewalls of the bonding film 77 and the upper portion 74. As a result, the depth of the edge molding material 75 is greater than the depth of the upper portion 74 in the normal direction (for example, the Z direction) of the package structure 10. In some embodiments, the width of the upper portion 74 is less than the width of the base portion 72 in a direction (for example, the X direction) that is perpendicular to the normal direction of the package structure 10. For example, the width of the edge molding material 75 on one side of the dummy die 70 is ranged from about 1 nm to about 3000 nm. In some embodiments, the depth of the base portion 72 is ranged from about 100 μm to about 300 μm, and the depth of the upper portion 74 is greater than the depth of the base portion 72. With the above arrangement, sufficient edge molding material 75 may be provided to mitigate the coefficient of thermal expansion (CTE) mismatch between the dummy die 70 and the package molding material 152, and reduce the corner stress of the package structure 10.

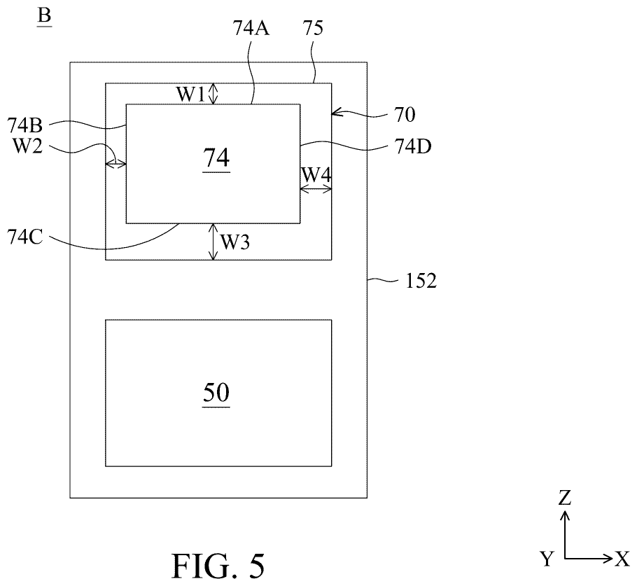

FIG. 5 illustrates an enlarged view of the region B shown in FIG. 1 in accordance with some embodiments. As shown in FIG. 5, the dummy die 70 is disposed closer to a corner of the package molding material 152 (and a corner of the package substrate 202, referring to FIG. 3L, for example) than the device die 50. In some embodiments, the width of the edge molding material 75 is variable around the upper portion 74 of the dummy die 70. In other words, the width of the edge molding material 75 is different on each edge of one of the upper portions 74. In particular, the upper portions 74 has a first side 74A, a second side 74B, a third side 74C, and a fourth side 74D. The first side 74A and the second side 74B face the corner of the package molding material 152, and the third side 74C and the fourth side 74D face the adjacent device die 50. In some embodiments, the first width W1 of the edge molding material 75 on the first side 74A is less than the third width W3 of the edge molding material 75 on the third side 74C, and the second width W2 of the edge molding material 75 on the second side 74B is less than the fourth width W4 of the edge molding material 75 on the fourth side 74D. As a result, the edge molding material 75 may be thickened on the sides of the dummy dies 70 facing the device dies 50 so as to provide more buffer between the dummy dies 70 and the device dies 50, thereby reducing the risk of damage to the device dies 50. It should be noted that the width of the edge molding material 75 can be adjustable by setting the locations of the scribe lines during the formation of the dummy dies 70.

Embodiments of package structures and methods for fabricating the same are provided. The package structure includes a dummy die disposed adjacent to the device die, and the dummy die includes an edge molding material on edges of the dummy die. The dummy die is disposed at a corner of the package molding material. The Young's modulus of the edge molding material is less than the Young's modulus of the package molding material around the dummy die and the device die. As a result, the edge molding material of the dummy die can mitigate the coefficient of thermal expansion (CTE) mismatch between the dummy die and the package molding material, and therefore the corner stress of the package structure can be reduced. In this way, cracks or other defects can be minimized for the package structure. In addition, the edge molding material may be thickened on the sides of the dummy dies facing the device dies so as to provide more buffer between the dummy dies and the device dies, thereby reducing the risk of damage to the device dies.

In some embodiments, a package structure is provided. The package structure includes a device die bonded to a package substrate via a plurality of connectors. The package structure includes a dummy die bonded to the package substrate via a plurality of dummy connectors and disposed adjacent to the device die. The dummy die includes a base portion, an upper portion bonded to the base portion, and an edge molding material formed over the base portion and surrounding the upper portion. The package structure also includes a package molding material over the package substrate and around the dummy die and the device die. The Young's modulus of the edge molding material is less than the Young's modulus of the package molding material.

In some embodiments, a package structure is provided. The package structure includes a device die bonded to a package substrate. The package structure includes a dummy die bonded to the package substrate and disposed adjacent to the device die. The dummy die includes a base portion and an upper portion bonded to the base portion. The width of the upper portion is less than the width of the base portion in the direction perpendicular to the normal direction of the package structure. The dummy die also includes an edge molding material formed over an upper surface of the base portion and covering sidewalls of the upper portion. The package structure also includes a package molding material over the package substrate and around the dummy die and the device die.

In some embodiments, a method for fabricating a package structure is provided. The method includes forming a dummy die, which includes bonding a plurality of upper portions to a base portion via a bonding film, forming an edge molding material over the base portion and around the upper portions, and performing a singulation process along a scribe line between the upper portions to form the dummy die. The method includes bonding the dummy die and a device die over a package substrate. The method includes forming an underfill between the dummy die and the package substrate. The underfill covers a portion of a sidewall of the edge molding material. The method also includes forming a package molding material over the package substrate and around the dummy die and the device die. The package molding material contacts the underfill and the edge molding material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a device die bonded to a package substrate via a plurality of connectors;
a dummy die bonded to the package substrate via a plurality of dummy connectors and disposed adjacent to the device die, wherein the dummy die comprises:
a base portion;
an upper portion bonded to the base portion; and
an edge molding material formed over the base portion and surrounding the upper portion; and
a package molding material over the package substrate and around the dummy die and the device die, wherein a Young's modulus of the edge molding material is less than a Young's modulus of the package molding material.

2. The package structure as claimed in claim 1, wherein the dummy die is disposed at a corner of the package molding material.

3. The package structure as claimed in claim 1, further comprising:
an underfill between the dummy die and the package substrate and around the dummy connectors, wherein the underfill is sandwiched between the edge molding material and the package molding material.

4. The package structure as claimed in claim 1, wherein a width of the edge molding material on one side of the dummy die is ranged from about 1 nm to about 3000 nm.

5. The package structure as claimed in claim 4, wherein the width of the edge molding material is variable around the upper portion of the dummy die.

6. The package structure as claimed in claim 1, wherein a depth of the upper portion is greater than a depth of the base portion.

7. A package structure, comprising:
a device die bonded to a package substrate;
a dummy die bonded to the package substrate and disposed adjacent to the device die, wherein the dummy die comprises:
a base portion;
an upper portion bonded to the base portion, wherein a width of the upper portion is less than a width of the base portion in a direction perpendicular to a normal direction of the package structure; and
an edge molding material formed over an upper surface of the base portion and covering sidewalls of the upper portion; and
a package molding material over the package substrate and around the dummy die and the device die.

8. The package structure as claimed in claim 7, wherein a depth of the edge molding material is greater than a depth of the upper portion in the normal direction of the package structure.

9. The package structure as claimed in claim 7, wherein the upper portion is bonded to the base portion via a bonding film, and the edge molding material covers sidewalls of the bonding film.

10. The package structure as claimed in claim 7, wherein the package molding material is in contact with the edge molding material.

11. The package structure as claimed in claim 10, further comprising:
an underfill between the dummy die, the device die and the package substrate, wherein the underfill extends into a gap between the edge molding material and the package molding material.

12. The package structure as claimed in claim 7, wherein the dummy die is disposed closer to a corner of the package substrate than the device die.

13. The package structure as claimed in claim 7, wherein a depth of the base portion is ranged from about 100 μm to about 300 μm.

14. The package structure as claimed in claim 7, wherein a glass transition temperature of the edge molding material is less than a glass transition temperature of the package molding material.

15. A method for forming a package structure, comprising:
forming a dummy die, comprising:
bonding a plurality of upper portions to a base portion via a bonding film;
forming an edge molding material over the base portion and around the upper portions; and
performing a singulation process along a scribe line between the upper portions to form the dummy die;
bonding the dummy die and a device die over a package substrate;
forming an underfill between the dummy die and the package substrate, wherein the underfill covers a portion of a sidewall of the edge molding material; and
forming a package molding material over the package substrate and around the dummy die and the device die, wherein the package molding material contacts the underfill and the edge molding material.

16. The method as claimed in claim 15, wherein forming the dummy die further comprises:
forming a plurality of dummy connectors over the base portion;
forming an attach film over the dummy connectors; and
bonding the base portion to a carrier via the attach film, wherein the upper portions are bonded to the base portion on the carrier.

17. The method as claimed in claim 16, wherein forming the dummy die further comprises:
removing the attach film to release the base portion from the carrier;
placing the upper portions and the base portion on a tape; and
performing the singulation process on the tape.

18. The method as claimed in claim 15, wherein the edge molding material is formed on each edge of one of the upper portions, wherein a width of the edge molding material is different on each edge of one of the upper portions.

19. The method as claimed in claim 15, wherein bonding the dummy die and the device die over the package substrate further comprises:
disposing the dummy die closer to a corner of the package substrate than the device die.

20. The method as claimed in claim 15, wherein forming the dummy die further comprises:
thinning down the base portion before bonding the upper portions to the base portion via the bonding film.
